(19) United States
(12) Patent Application Publication
(10) Pub. No.: US 2024/0113663 A1
(43) Pub. Date: Apr. 4, 2024

(54) DOHERTY AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/476,773

(22) Filed: Sep. 28, 2023

(30) Foreign Application Priority Data
Sep. 29, 2022 (JP) 2022-156825

(51) Int. Cl. H03F 1/02

(52) U.S. Cl. CPC H03F 1/0288; H03F 2200/102; H03F 2200/451

(57) ABSTRACT

A Doherty amplifier circuit includes a carrier amplifier including one or more amplifiers, and a peaking amplifier including one or more amplifiers. At least one of the amplifiers includes a transistor and a feedback circuit. The transistor receives, at its base or gate, a radio frequency signal and a bias voltage or current which changes, and outputs an amplified radio frequency signal from its collector or drain. The feedback circuit provides, to the base or gate or the emitter or source of the transistor, a voltage or a current based on the amplified radio frequency signal.

### CROSS REFERENCE TO RELATED APPLICATION

This application claims priority from Japanese Patent Application No. 2022-156825 filed on Sep. 29, 2022. The content of this application is incorporated herein by reference in its entirety.

### BACKGROUND ART

The present disclosure relates to a Doherty amplifier circuit.

U.S. Patent Application Publication No. 2019/0149099 describes a Doherty amplifier circuit which changes the bias point of its peaking amplifier. Change of the bias point enables the gain of the peaking amplifier to be controlled.

When the bias point of a common-emitter amplifier is changed, its input impedance or its transmission phase characteristics may change to a large extent. The change of the characteristics of a common-emitter amplifier may affect the transmission phase characteristics of the carrier amplifier and those of the peaking amplifier of a related Doherty amplifier circuit. In a Doherty amplifier circuit, the relationship between the transmission phase characteristics of the carrier amplifier and those of the peaking amplifier is suitable. Desirably, the transmission phase characteristics of the carrier amplifier and those of the peaking amplifier do not change. Therefore, as a result of the change of the characteristics of a common-emitter amplifier, a related Doherty amplifier circuit may fail to obtain good characteristics (a radio-frequency output signal is distorted).

### BRIEF SUMMARY

The present disclosure suppresses change of the characteristics.

A Doherty amplifier circuit according to an aspect of the present disclosure includes a carrier amplifier including one or more amplifiers, and a peaking amplifier including one or more amplifiers. At least one of the amplifiers includes a transistor and a feedback circuit. The transistor receives, at a base or gate thereof, a radio frequency signal and a bias voltage or current which changes, and outputs, from a collector or drain thereof, an amplified radio frequency signal. The feedback circuit provides, to the base or gate or an emitter or source of the transistor, a voltage or a current based on the amplified radio frequency signal.

The present disclosure enables suppression of change of the characteristics.

### BRIEF DESCRIPTION OF THE DRAWINGS

FIG. 1 is a diagram illustrating the configuration of a Doherty amplifier circuit according to a first embodiment;

FIG. 2 is a diagram illustrating the configuration of a variable-gain amplifier in a Doherty amplifier circuit according to the first embodiment;

FIG. 3 is a diagram illustrating a circuit simulation result of an amplifier according to a comparison example;

FIG. 4 is a diagram illustrating a circuit simulation result of a variable-gain amplifier according to the first embodiment;

FIG. 5 is a diagram illustrating the configuration of a variable-gain amplifier according to a second embodiment;

FIG. 6 is a diagram illustrating a first layout example according to a comparison example;

FIG. 7 is a diagram illustrating a second layout example according to the comparison example;

FIG. 8 is a diagram illustrating a layout example of a variable-gain amplifier according to the second embodiment; and

FIG. 9 is a diagram illustrating the configuration of an amplifier according to a third embodiment.

### DETAILED DESCRIPTION

Embodiments of the present disclosure will be described below in detail on the basis of the drawings. The embodiments do not limit the present disclosure. Needless to say, each embodiment is exemplary, and partial replacement or combination of configurations in different embodiments may be made. In a second embodiment and its subsequent embodiments, points common to those in a first embodiment will not be described, and only different points will be described. In particular, substantially the same operation and effect of substantially the same configuration will not be described in each embodiment.

### First Embodiment

### Configuration

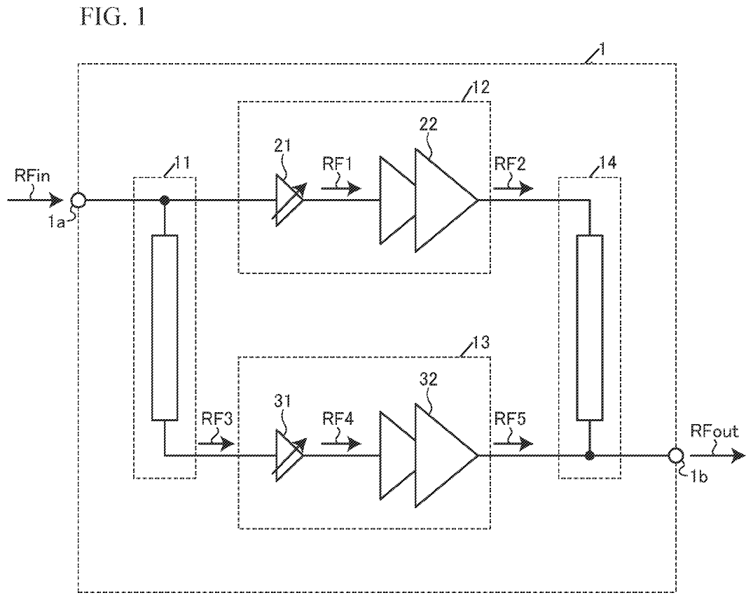

FIG. 1 is a diagram illustrating the configuration of a Doherty amplifier circuit according to the first embodiment. A Doherty amplifier circuit 1 amplifies a radio frequency signal RFin, which is received at an input terminal 1a, and outputs a radio frequency signal RFout from an output terminal 1b.

The Doherty amplifier circuit 1 includes a divider 11, a carrier amplifier 12, a peaking amplifier 13, and a coupler 14.

The carrier amplifier 12 includes an upstream amplifier 21 and a downstream amplifier 22. The amplifier 21 is a variable-gain amplifier. The amplifier 22 is not a variable-gain amplifier.

The peaking amplifier 13 includes an upstream amplifier 31 and a downstream amplifier 32. The amplifier 31 is a variable-gain amplifier. The amplifier 32 is not a variable-gain amplifier.

The gain of amplifier 21 and that of the amplifier 31 are variable through change of their bias points.

In the first embodiment, each of the carrier amplifier 12 and the peaking amplifier 13 includes two amplifiers. However, the present disclosure is not limited to this. Each of the carrier amplifier 12 and the peaking amplifier 13 may include one amplifier or three or more amplifiers.

In the first embodiment, the upstream amplifiers 21 and 31 are variable-gain amplifiers. However, the present disclosure is not limited to this. The carrier amplifier 12 and the peaking amplifier 13 may have any configuration as long as at least one of the amplifiers included in the carrier amplifier 12 and the peaking amplifier 13 is a variable-gain amplifier.

The Doherty amplifier circuit 1 has good efficiency if the peaking amplifier 13 is operated at minimum required. Therefore, at least one of the amplifiers included in the peaking amplifier 13 can be a variable-gain amplifier.

The efficiency of the amplifiers 21 and 31 is improved directly through change of their bias points. Control of the gain of the upstream amplifiers 21 and 31 causes a decrease of power consumption of the downstream amplifiers 22 and 32. That is, the efficiency of the downstream amplifiers 22 and 32 is improved indirectly through change of the bias points of the upstream amplifiers 21 and 31. If the bias points of the downstream amplifiers 22 and 32 may be changed, the efficiency of the downstream amplifiers 22 and 32 is improved directly.

The amplifier 21 outputs, to the amplifier 22, a radio frequency signal RF1 obtained by amplifying the radio frequency signal RFin. The amplifier 22 outputs, to the coupler 14, a radio frequency signal RF2 obtained by amplifying the radio frequency signal RF1.

The divider 11 outputs, to the amplifier 31, a radio frequency signal RF3 whose phase is different from that of the radio frequency signal RFin by approximately 90°. “Approximately 90°” encompasses, not only the phase of 90°, but also a phase of 90°±45°. For example, the divider 11 is a 90° hybrid circuit. However, the present disclosure is not limited to this.

The amplifier 31 outputs, to the amplifier 32, a radio frequency signal RF4 obtained by amplifying the radio frequency signal RF3. The amplifier 32 outputs, to the coupler 14, a radio frequency signal RF5 obtained by amplifying the radio frequency signal RF4.

The coupler 14 outputs, from the output terminal 1b of the Doherty amplifier circuit 1, the radio frequency signal RFout obtained by combining the radio frequency signal RF2 and the radio frequency signal RF5.

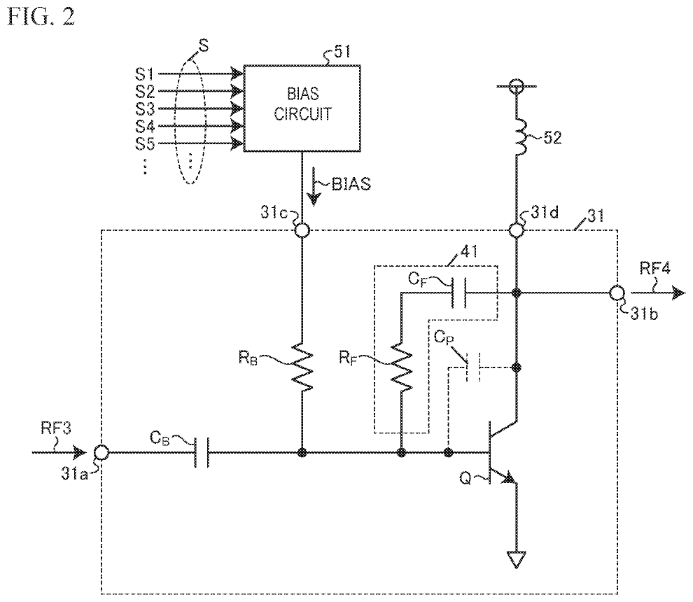

FIG. 2 is a diagram illustrating the configuration of a variable-gain amplifier in a Doherty amplifier circuit according to the first embodiment. FIG. 2 illustrates the configuration of the amplifier 31. The configuration of the amplifier 21 is substantially the same as that of the amplifier 31, and will be neither illustrated nor described.

The amplifier 31 amplifies the radio frequency signal RF3, which is received at an input terminal 31a, and outputs the radio frequency signal RF4 from an output terminal 31b. The amplifier 31 receives a bias current or bias voltage BIAS at an input terminal 31c from a bias circuit 51.

The bias circuit 51 is capable of changing the bias current or bias voltage BIAS on the basis of a received signal S for output to the input terminal 31c of the amplifier 31. This makes the bias point of the amplifier 31 variable, and makes the gain variable.

For example, the signal S includes signals S1 to S5. For example, the signal S1 is an envelope tracking signal which changes in accordance with the envelopes of the radio frequency signal RFin. For example, the signal S2 represents the power supply voltage supplied to the Doherty amplifier circuit 1. For example, the signal S3 represents the temperature of the Doherty amplifier circuit 1. For example, the signal S4 represents the saturation state of the carrier amplifier 12. For example, the signal S5 represents the reflection power of the Doherty amplifier circuit 1. However, the present disclosure is not limited to these.

The amplifier 31 includes a capacitor C_{B}, a resistor R_{B}, a transistor Q, and a feedback circuit 41.

In the first embodiment, each transistor is a bipolar transistor. However, the present disclosure is not limited to this. For example, the bipolar transistor is a heterojunction bipolar transistor (HBT). However, the present disclosure is not limited to this. The transistor may be, for example, a field effect transistor (FET). The transistor may be a multi-finger transistor in which multiple unit transistors are electrically coupled in parallel to each other. A unit transistor refers to the minimum configuration included in a transistor.

When each transistor is a FET, the drain of the FET corresponds to the collector of a bipolar transistor; the gate of the FET corresponds to the base of the bipolar transistor; the source of the FET corresponds to the emitter of the bipolar transistor.

The capacitor C_{B} is electrically coupled, at its first end, to the input terminal 31a. The capacitor C_{B} is electrically coupled, at its second end, to the base of the transistor Q. The capacitor C_{B} is a DC-cut capacitor which cuts direct-current components of the radio frequency signal RF3.

The resistor R_{B} is electrically coupled, at its first end, to the input terminal 31c. The resistor R_{B} is electrically coupled, at its second end, to the base of the transistor Q.

The transistor Q is electrically coupled, at its emitter to a reference potential. For example, the reference potential is the ground potential. However, the present disclosure is not limited to this. The transistor Q is supplied, at its collector, with the power supply voltage through an input terminal 31d and a choke coil 52. The transistor Q amplifies the radio frequency signal RF3, which is received at its base, and outputs the radio frequency signal RF4 from its collector to the output terminal 31b.

The feedback circuit 41 is electrically coupled between the base and the collector of the transistor Q. The feedback circuit 41 includes a resistor R_{F} and a capacitor C_{F}. The resistor R_{F} and the capacitor C_{F} are coupled in series to each other. The resistor R_{F} is electrically coupled, at its first end, to the base of the transistor Q. The resistor R_{F} is electrically coupled, at its second end, to a first end of the capacitor C_{F}. The capacitor C_{F} is electrically coupled, at its second end, to the collector of the transistor Q.

In the first embodiment, the resistor R_{F} is electrically coupled to the base of the transistor Q; the capacitor C_{F} is electrically coupled to the collector of the transistor Q. However, the present disclosure is not limited to this. The resistor R_{F} may be electrically coupled to the collector of the transistor Q; the capacitor C_{F} may be electrically coupled to the base of the transistor Q.

The transistor Q has a parasitic capacitance C_{P} between its base and its collector. The parasitic capacitance C_{P} is a junction capacitance between the base (P-type semiconductor) and the collector (N-type semiconductor).

### The Influence of the Parasitic Capacitance

Typically, in a common-emitter amplifier, a radio frequency signal, which is received at its base, is amplified, and the amplified signal serves as the collector current. The voltage, which occurs due to the collector current flowing through a load, is the collector voltage which is output from the common-emitter amplifier.

The capacitance value of the parasitic capacitance between the base and the collector of a transistor has a property of increasing as the amplitude of the collector voltage increases (more precisely, as the time in which the instantaneous value of the collector voltage approaches zero volt (V) is longer).

The parasitic capacitance, which connects between the input and the output of the transistor, is a feedback capacitance. Therefore, the property, in which the capacitance value of the parasitic capacitance changes in accordance with the amplitude of the collector voltage, causes change of the amount of feedback between the input and the output of the transistor. Thus, the characteristics (for example, the input impedance, the transmission phase characteristics) of the common-emitter amplifier change in accordance with the output power or the input power.

Therefore, if a common-emitter amplifier, whose transmission phase characteristics change in accordance with the output power or the input power, is used in a Doherty amplifier circuit, a suitable phase difference between the radio-frequency output signal from the carrier amplifier and the radio-frequency output signal from the peaking amplifier fails to be maintained, resulting in degradation of the characteristics.

### The Feature of the First Embodiment

In contrast, the amplifier 31 according to the first embodiment has the feedback circuit 41 which extends from the collector of the transistor Q through the resistor R_{F} to the base. The feedback circuit 41 provides a voltage amplitude or a current amplitude, which is based on the radio frequency signal RF4 obtained through amplification, to the base of the transistor Q. In addition, in the feedback circuit 41, the capacitor C_{F}, which is a DC-cut capacitor for interrupting a direct current, is electrically coupled in series to the resistor R_{F}.

For example, the resistance value of the resistor R_{F} is less than or equal to the impedance of the parasitic capacitance C_{P}. Thus, the amplifier 31 easily achieves stable characteristics regardless of the input power and the output power. This is because a low resistance value of the resistor R_{F} enables the amount of the feedback (the voltage amplitude or the current amplitude) through the feedback circuit 41 to be made larger than the amount of the feedback through the parasitic capacitance C_{P}. Therefore, if the parasitic capacitance C_{P} changes, the amount of the feedback through the feedback circuit 41 is larger than the amount of the feedback through the parasitic capacitance C_{P}. This causes the change of the amount of the feedback through the parasitic capacitance C_{P} to be made relatively small. As a result, the amplifier 31 may achieve stable characteristics regardless of the output power or the input power.

From substantially the same viewpoint, for example, the capacitance of the capacitor C_{F} is greater than or equal to the capacitance of the parasitic capacitance C_{P}. For example, when the capacitance value of the parasitic capacitance C_{P} is in the order of several picofarads (pF), an exemplary capacitance value of the capacitor C_{F} is in the order of several tens of pF.

### Circuit Simulation Result

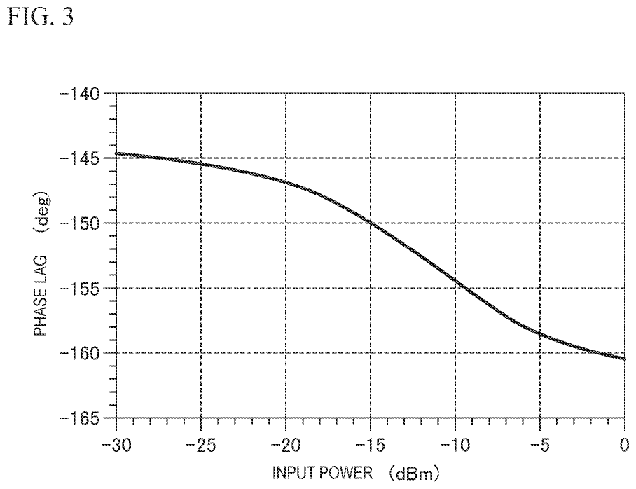

FIG. 3 is a diagram illustrating a circuit simulation result of an amplifier according to a comparison example. The comparison example does not include the feedback circuit 41 of the amplifier 31. In FIG. 3, the horizontal axis represents input power (dBm); the vertical axis represents phase lag (deg). The phase lag indicates how much the phase of the output voltage of the transistor Q lags behind the phase of the input voltage received by the transistor Q.

As illustrated in FIG. 3, in the comparison example without necessarily the feedback circuit 41, the phase lag changes by a large extent as the input power changes.

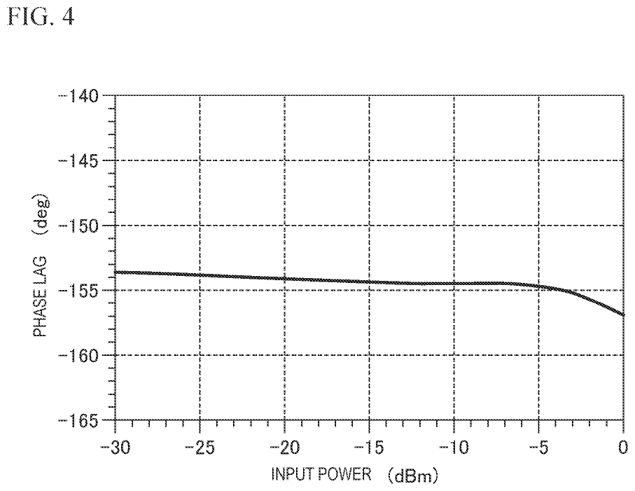

FIG. 4 is a diagram illustrating a circuit simulation result of a variable-gain amplifier according to the first embodiment. In FIG. 4, the horizontal axis represents input power (dBm); the vertical axis represents phase lag (deg).

Compared with FIG. 3, FIG. 4 shows that, even with change of the input power, change of the phase lag is suppressed in the amplifier 31 having the feedback circuit 41.

### Effects

The amplifier 31, which has the feedback circuit 41, achieves suppression of change of the characteristics (such as input impedance, transmission phase characteristics) of the transistor Q even when the output power or the input power changes. Thus, the Doherty amplifier circuit 1 achieves suppression of change of the phase difference between the radio frequency signal RF2, which is output by the carrier amplifier 12, and the radio frequency signal RF5, which is output by the peaking amplifier 13, achieving suppression of degradation of the characteristics (distortion of the radio frequency signal RFout).

### Second Embodiment

Among the components in the second embodiment, the same components as those in the first embodiment are designated with the same reference numerals, and will not be described.

The amplifier 31 according to the first embodiment, which has a single amplifier transistor, that is, the transistor Q, has a limitation on the output power. Accordingly, the amplifier transistor of an amplifier 31A according to the second embodiment includes multiple unit transistors. Thus, the amplifier 31A according to the second embodiment enables the output power to be increased.

### Configuration

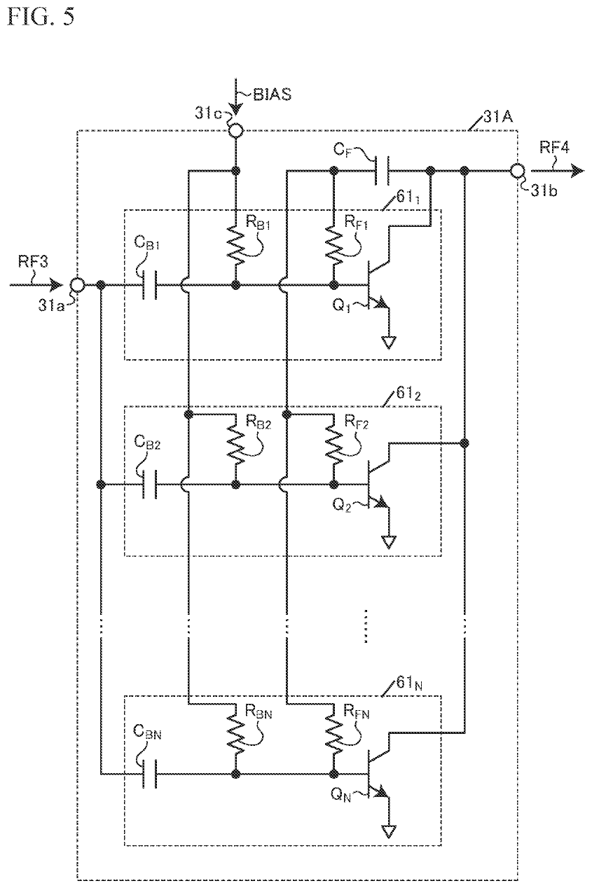

FIG. 5 is a diagram illustrating the configuration of a variable-gain amplifier according to the second embodiment.

The amplifier 31A includes the capacitor CF and cells 61₁, 61₂, . . . , 61_{N} (N is a natural number). The cells 61₁, 61₂, . . . , 61_{N} may be formed as a multi-finger (multi-cell) transistor, for example, on/in a gallium arsenide (GaAs) substrate or a silicon (Si) substrate. The capacitor CF may be also formed on/in the substrate on/in which the cells 61₁, 61₂, . . . , 61_{N} are formed.

The cell 61₁ includes a capacitor C_{B1}, a resistor R_{B1}, a resistor R_{F1}, and a transistor Q₁. The parasitic capacitance between the base and the collector of the transistor Q₁ is not illustrated. The connection relationship between the capacitor C_{B1}, the resistor R_{B1}, the resistor R_{F1}, and the transistor Q₁, which is substantially the same as that of the amplifier 31 (see FIG. 2), will not be described. The resistor R_{F1} is electrically coupled, at its second end, to the first end of the capacitor C_{F}.

The resistor R_{F1} and the capacitor CF form a feedback circuit between the base and the collector of the transistor Q₁.

The cell 61₂ includes a capacitor C_{B2}, a resistor R_{B2}, a resistor R_{F2}, and a transistor Q₂. The parasitic capacitance between the base and the collector of the transistor Q₂ is not illustrated. The connection relationship between the capacitor C_{B2}, the resistor R_{B2}, the resistor R_{F2}, and the transistor Q₂, which is substantially the same as that of the amplifier 31 (see FIG. 2), will not be described. The resistor R_{F2} is electrically coupled, at its second end, to the first end of the capacitor C_{F}.

The resistor R_{F2} and the capacitor C_{F} form a feedback circuit between the base and the collector of the transistor Q₂.

The cell 61_{N} includes a capacitor C_{BN}, a resistor R_{BN}, a resistor R_{FN}, and a transistor Q_{N}. The parasitic capacitance between the base and the collector of the transistor Q_{N} is not illustrated. The connection relationship between the capacitor C_{BN}, the resistor R_{BN}, the resistor R_{FN}, and transistor Q_{N}, which is substantially the same as that of the amplifier 31 (see FIG. 2), will not be described. The resistor R_{FN} is electrically coupled, at its second end, to the first end of the capacitor C_{F}.

The resistor R_{FN} and the capacitor C_{F} form a feedback circuit between the base and the collector of the transistor Q_{N}.

That is, the capacitor C_{F} is shared in the feedback circuits of the cells 61₁, 61₂, . . . , 61_{N}. The capacitor C_{F}, which is a DC-cut capacitor, is shareable.

The transistors Q₁, Q₂, . . . , Q_{N} correspond to exemplary “unit transistors” in the present disclosure. The resistors R_{F1}, R_{F2}, . . . , R_{FN} correspond to exemplary “unit resistors” in the present disclosure.

### Comparison Example

A comparison example does not employ sharing of the capacitor C_{F} and includes capacitors for the respective cells. That is, amplifiers 31, whose number is N and each of which is illustrated in FIG. 2, are simply connected in parallel to each other.

### A First Layout Example of the Comparison Example

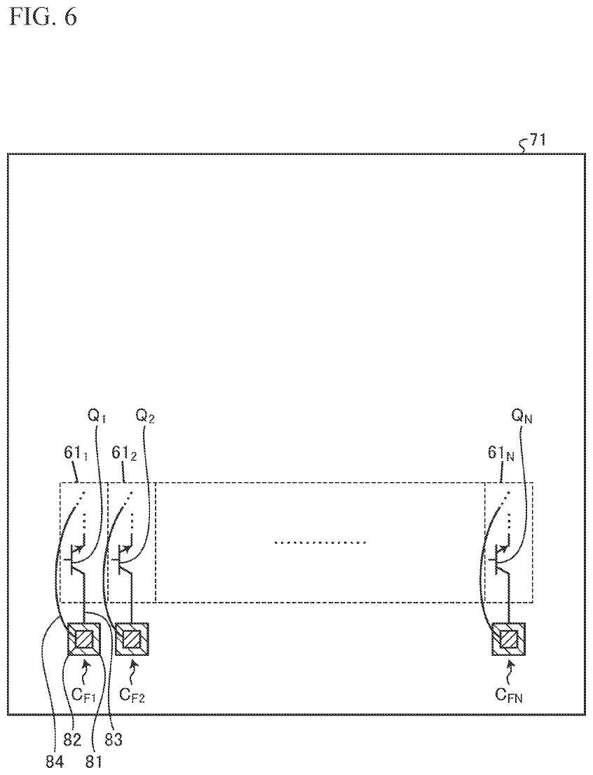

FIG. 6 is a diagram illustrating a first layout example of the comparison example.

The cells 61₁, 61₂, . . . , 61_{N} are formed in a substrate 71 without necessarily spacing in a direction (from left to right in FIG. 6).

Capacitors C_{F1}, C_{F2}, . . . , C_{FN} are formed on/in the substrate 71 with spacing in the direction.

The line of the cells 61₁, 61₂, . . . , 61_{N} is parallel to the line of the capacitors C_{F1}, C_{F2}, . . . , C_{FN}.

The capacitor C_{F1} includes a relatively-low-layer plate 81 and a relatively-high-layer plate 82. For clarity of the drawing, FIG. 6 illustrates the plates 81 and 82 having different sizes. However, they may have the same size.

The transistor Q₁ in the cell 61₁ is electrically coupled, at its collector, to the plate 81 through a wire 83.

A wire 84, which electrically couples the resistor R_{F1} (see FIG. 5) in the cell 61₁ to the plate 82, needs to be routed in an upper layer (or a lower layer) of the cell 61₁.

### A Second Layout Example of the Comparison Example

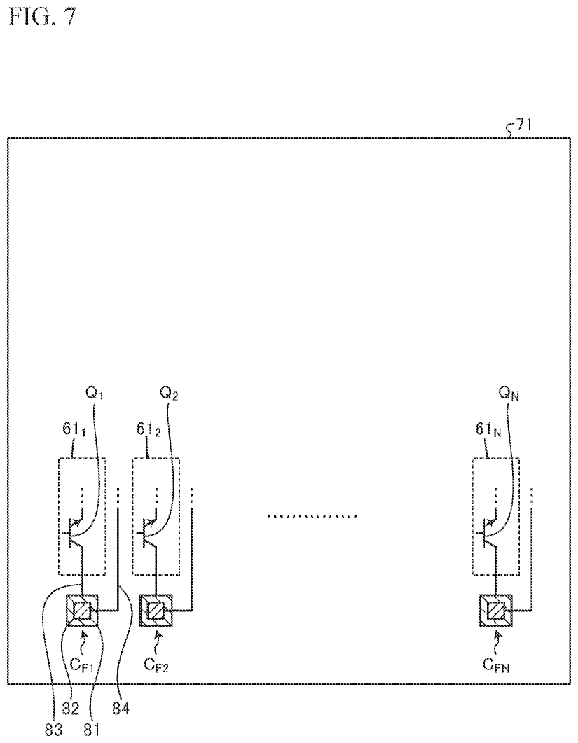

FIG. 7 is a diagram illustrating a second layout example of the comparison example. Configurations, in the second layout example, common to those of the first layout example will not be described.

The cells 61₁, 61₂, . . . , 61_{N} are formed on/in the substrate 71 with spacing in a direction.

The wire 84, which electrically couples the resistor R_{F1} (see FIG. 5) in the cell 61₁ to the plate 82, needs to be routed between the cell 61₁ and the cell 61₂.

### A Layout Example of the Second Embodiment

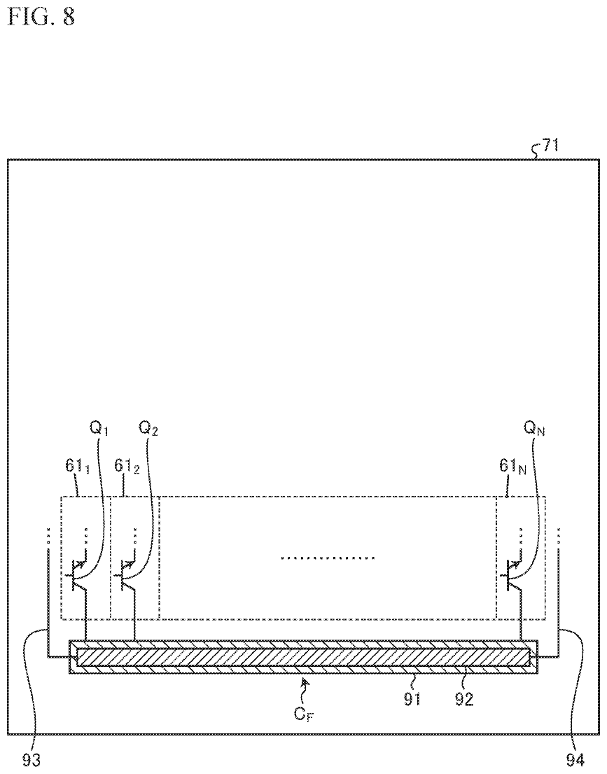

FIG. 8 is a diagram illustrating a layout example of a variable-gain amplifier according to the second embodiment. Configurations, in the layout example of the second embodiment, common to the layout examples of the comparison example will not be described.

The cells 61₁, 61₂, . . . , 61_{N} are formed on/in the substrate 71 without necessarily spacing in a direction.

The capacitor C_{F} has a rectangular shape extending in the direction.

The capacitor C_{F} includes a relatively-low-layer plate 91 and a relatively-high-layer plate 92. For clarity of the drawing, FIG. 8 illustrates the plates 91 and 92 having different sizes. However, they may have the same size.

The line of the cells 61₁, 61₂, . . . , 61_{N} is parallel to the capacitor C_{F}.

For example, the width, in the direction, of the line of the cells 61₁, 61₂, . . . , 61_{N} is approximately the same as that of the capacitor C_{F}.

A wire 93, which electrically couples the resistors R_{F1}, R_{F2}, . . . , R_{FN} (see FIG. 5) in the cells 61₁, 61₂, . . . , 61_{N} to the plate 92, extends on a surface of the substrate 71 along the left side, in FIG. 8, of the cell 61₁. A wire 94, which electrically couples the resistors R_{F1}, R_{F2}, . . . , R_{FN} in the cells 61₁, 61₂, . . . , 61_{N} to the plate 92, extends on the surface of the substrate 71 along the right side, in FIG. 8, of the cell 61_{N}.

Either one of the wire 93 and the wire 94 may be provided. If both the wire 93 and the wire 94 are provided, the layout has a good symmetric property.

### Effects

Compared with the first layout example (see FIG. 6) of the comparison example, in the layout example (see FIG. 8) of the second embodiment, the wire 93 and the wire 94 may be formed on the surface of the substrate 71 without necessarily being routed in an upper layer (or a lower layer) of the cells 61₁, 61₂, . . . , 61_{N}, particularly without necessarily being routed on the base or gate side of each of the cells 61₁, 61₂, . . . , 61_{N}.

Compared with the second layout example (see FIG. 7), in the layout example (see FIG. 8) of the second embodiment, the number of the wire 93 and the wire 94 is made less. In addition, the width, in the direction, of the line of the cells 61₁, 61₂, . . . , 61_{N} may be made short.

### Third Embodiment

The same components, among the components of the third embodiment, as those of the other embodiments are designated with the same reference numerals, and will not be described.

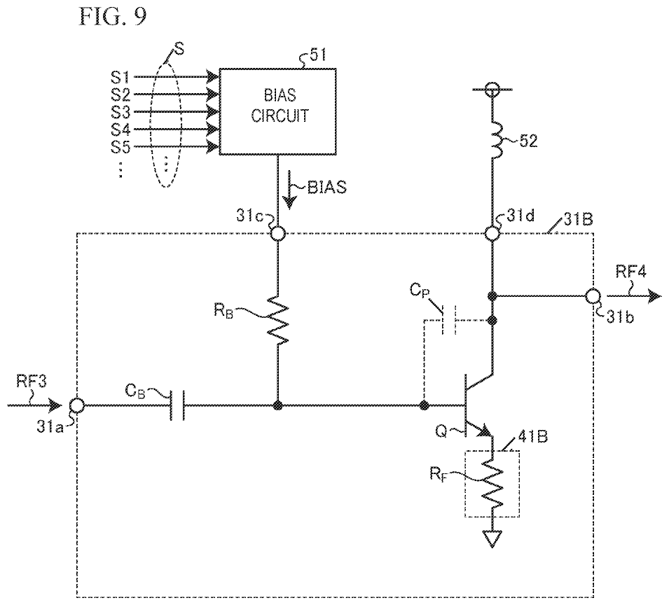

FIG. 9 is a diagram illustrating the configuration of an amplifier according to the third embodiment.

Compared with the amplifier 31 (see FIG. 2), an amplifier 31B includes a feedback circuit 41B instead of the feedback circuit 41.

The feedback circuit 41B is electrically coupled between the emitter of the transistor Q and the reference potential. The feedback circuit 41B includes the resistor R_{F}. The resistor R_{F} is electrically coupled, at its first end, to the emitter of the transistor Q. The resistor R_{F} is electrically coupled, at its second end, to the reference potential.

### Effects

(1)

The resistor R_{F} generates a voltage drop proportional to the emitter current (≈the collector current) of the transistor Q.

When the emitter current of the transistor Q increases, the amount of the voltage drop of the resistor R_{F} increases. This increases the emitter potential of the transistor Q, and decreases the voltage between the base and the emitter of the transistor Q. As a result, the output current from the transistor Q decreases.

When the emitter current of the transistor Q decreases, the amount of the voltage drop of the resistor R_{F} decreases. This decreases the emitter potential of the transistor Q, and increases the voltage between the base and the emitter of the transistor Q. As a result, the output current from the transistor Q increases.

That is, the resistor R_{F} is a series negative feedback circuit.

As described above, a negative feedback effect is obtained by using the resistor R_{F}. That is, the resistor R_{F} is a feedback circuit which provides, to the base of the transistor Q, a voltage drop based on the radio frequency signal RF4 obtained through amplification (some of the high frequency components of the collector current (≈the emitter current) of the transistor Q). Like the amplifier 31 according to the first embodiment, this negative feedback achieves suppression of degradation of the characteristics (distortion of the radio frequency signal RFout).

(2)

Compared with the amplifier 31 (see FIG. 2), the amplifier 31B has stability (tolerance) against damage.

The bias circuit 51 (see FIG. 2) follows change of the state rapidly (for example, in the order of several nanoseconds (nsec)). Thus, the bias circuit 51 does not have computations and functions, which lead to a slowdown, as much as possible. Therefore, the amplifier 31 may receive application of a high voltage, which has not been limited, to the base of the transistor Q. As a result, a large voltage may be applied between the base and the emitter of the transistor Q, and a large current may flow through the collector, resulting in terrible damage to the transistor Q.

In contrast, in the amplifier 31B, the resistor R_{F} is electrically coupled between the emitter of the transistor Q and the reference potential. When a large voltage is applied to the base of the transistor Q and a current flows through the collector, approximately the same current as the collector current flows through the emitter. Then, a voltage drop occurs at the resistor R_{F}, which increases the emitter potential of the transistor Q. As a result, application of a large voltage between the base and the emitter of the transistor Q is suppressed, resulting in suppression of occurrence of terrible damage to the transistor Q.

(3]

Compared with the amplifier 31 (see FIG. 2), the amplifier 31B has stability against oscillation.

When the bias circuit 51 is used to change the bias point intentionally, a bias condition, in which the amplifier 31 easily oscillates, is highly likely to occur. For example, at an instantaneously high bias, the high bias makes the current amplification factor of the transistor Q high, and the amplifier 31 easily oscillates. When the temperature of the transistor Q is low, the transistor Q has a high current amplification factor, and the amplifier 31 easily oscillates.

When a parasitic capacitance occurs across the resistor R_{F}, the amplifier 31 (see FIG. 2) may have positive feedback at high frequency, causing the amplifier 31 to oscillate.

In contrast, even when a parasitic capacitance occurs across the resistor R_{F}, the amplifier 31B does not have positive feedback, making it difficult for the amplifier 31B to oscillate.

### The Configuration Examples of the Present Disclosure

The present disclosure may employ the configurations described below.

(1)

A Doherty amplifier circuit comprising:
a carrier amplifier including one or more amplifiers; and
a peaking amplifier including one or more amplifiers,
wherein at least one of the amplifiers includes
   a transistor that receives, at a base or gate thereof, a radio frequency signal and a bias voltage or current which changes, and that outputs, from a collector or drain thereof, an amplified radio frequency signal, and
   a feedback circuit that provides, to the base or gate or an emitter or source of the transistor, a voltage or a current based on the amplified radio frequency signal.
      (2)

The Doherty amplifier circuit according to (1),
wherein the feedback circuit includes a resistor electrically coupled between the base or gate and the collector or drain of the transistor.
   (3)

The Doherty amplifier circuit according to (2),
wherein the feedback circuit further includes a capacitor coupled in series to the resistor.
   (4)

The Doherty amplifier circuit according to (3),
wherein the at least one of the amplifiers includes a plurality of cells each including a plurality of unit transistors comprised by the transistor and each including a plurality of unit resistors comprised by the resistor, and
wherein the capacitor is disposed as a common capacitor for the plurality of cells.
   (5)

The Doherty amplifier circuit according to (4),
wherein, in the at least one of the amplifiers,
   the plurality of cells are arrayed in a direction,
   the capacitor includes
      a first plate that extends in the direction and that is electrically coupled to collectors or drains of the plurality of unit transistors, and
      a second plate that extends in the direction and that is opposite the first plate, and
   one or two wires which electrically couple between the second plate and the plurality of unit resistors are disposed from either one or both of end portions of the second plate through outside of either one or both of end portions of the plurality of cells.
      (6)

The Doherty amplifier circuit according to (1),
wherein the feedback circuit includes a resistor that is electrically coupled between the emitter or source of the transistor and a reference potential.
   (7)

The Doherty amplifier circuit according to any one of (1) to (6),
wherein the bias voltage or current changes based on at least one of an envelope of a radio frequency signal, a power supply voltage, a temperature, a saturation state of the carrier amplifier, and reflection power.

The embodiments described above are made for easy understanding of the present disclosure, not for limited interpretation of the present disclosure. The present disclosure may be changed/improved without necessarily departing from its gist. The present disclosure encompasses its equivalents.

What is claimed is:

1. A Doherty amplifier circuit comprising:
a carrier amplifier comprising one or more first amplifiers; and
a peaking amplifier comprising one or more second amplifiers,
wherein at least one amplifier of the first amplifiers or the second amplifiers comprises:
a transistor that receives a radio frequency signal and that receives a changing bias voltage or a changing bias current at a base or a gate of the transistor, and that outputs an amplified radio frequency signal from a collector or a drain of the transistor, and
a feedback circuit configured to provide a voltage or a current based on the amplified radio frequency signal to the base or the gate of the transistor, or to an emitter or a source of the transistor.

2. The Doherty amplifier circuit according to claim 1, wherein the feedback circuit comprises a resistor electrically coupled between the base or the gate of the transistor and the collector or the drain of the transistor.

3. The Doherty amplifier circuit according to claim 2, wherein the feedback circuit further comprises a capacitor coupled in series to the resistor.

4. The Doherty amplifier circuit according to claim 3,
wherein the at least one amplifier comprises a plurality of cells, each cell comprising a plurality of unit transistors of the transistor, and each cell comprising a plurality of unit resistors of the resistor, and
wherein the capacitor is a common capacitor for the plurality of cells.

5. The Doherty amplifier circuit according to claim 4, wherein in the at least one amplifier:
the plurality of cells are arrayed in a direction,
the capacitor comprises:
a first plate that extends in the direction and that is electrically coupled to collectors or drains of the plurality of unit transistors, and
a second plate that extends in the direction and that is opposite the first plate, and
wherein one or two wires which electrically couple the second plate and the plurality of unit resistors are from either one or both ends of the second plate through an outside of either one or both ends of the plurality of cells.

6. The Doherty amplifier circuit according to claim 1, wherein the feedback circuit comprises a resistor that is electrically coupled between the emitter or the source of the transistor and a reference potential.

7. The Doherty amplifier circuit according to claim 1, wherein the bias voltage or the bias current changes based on an envelope of a radio frequency signal amplified by the Doherty amplifier circuit.

8. The Doherty amplifier circuit according to claim 1, wherein the bias voltage or the bias current changes based on a power supply voltage of the Doherty amplifier circuit.

9. The Doherty amplifier circuit according to claim 1, wherein the bias voltage or the bias current changes based on a temperature of the Doherty amplifier circuit.

10. The Doherty amplifier circuit according to claim 1, wherein the bias voltage or the bias current changes based on a saturation state of the carrier amplifier.

11. The Doherty amplifier circuit according to claim 1, wherein the bias voltage or the bias current changes based on a reflection power of the Doherty amplifier circuit.
